(19) United States
(12) Patent Application Publication
(10) Pub. No.: US 2023/0253061 A1
(43) Pub. Date: Aug. 10, 2023

(54) MECHANICAL INTERCONNECT MEMORY

(71) Applicant: KOREA ADVANCED INSTITUTE OF SCIENCE AND TECHNOLOGY, Daejeon (KR)

(72) Inventors: Jun-Bo YOON, Daejeon (KR); Yong-bok Lee, Daejeon (KR); Pan-kyu Choi, Daejeon (KR); Su-hyun Kim, Daejeon (KR); Tae-Soo Kim, Daejeon (KR)

(73) Assignee: KOREA ADVANCED INSTITUTE OF SCIENCE AND TECHNOLOGY, Daejeon (KR)

(21) Appl. No.: 17/951,544

(22) Filed: Sep. 23, 2022

(30) Foreign Application Priority Data
Feb. 4, 2022 (KR) 10-2021-0015125

(51) Int. Cl. G11C 23/00

(52) U.S. Cl. CPC G11C 23/00

(57) ABSTRACT

The present invention relates to a mechanical interconnect memory, and more particularly, to a mechanical interconnect memory applicable to smart interconnect technology that reduces the power consumption of an interconnect layer.

A mechanical interconnect memory according to an embodiment of the present invention comprises: an upper electrode including: a spring part having at least one upward protruding portion between both ends of the spring part; and a moving part having one end of the moving part fixed to the at least one upward protruding portion of the spring part and the other end of the moving part being a free end of the moving part that is capable of moving up and down; and a lower electrode at least partially disposed under the moving part.

### CROSS-REFERENCE TO RELATED APPLICATIONS

This application claims priority to Korean Patent Application No. 10-2022-0015125 filed on Feb. 4, 2022 in the Korean Intellectual Property Office, the entire contents of which are hereby incorporated by reference.

### TECHNICAL FIELD

The present disclosure relates to a mechanical interconnect memory, and more particularly, to a mechanical interconnect memory applicable to a smart interconnect technology that reduces power consumption of an interconnect layer.

### BACKGROUND ART

FIGS. 1(a) to 1(c) are graphs for explaining a fundamental problem that occurs according to the miniaturization of semiconductors.

The following “Equation 1” represents the power consumption (P) of a semiconductor device.

$$P = \frac{{V}_{DD} {I}_{leak} ( {e}^{- \frac{{V}_{th}}{( kt / q )}} )}{static power consumption} + \frac{a {C}_{tot} {V}_{DD}^{2} f}{dynamic power consumption} \qquad Equation 1$$

As semiconductors are miniaturized, the leakage current (Iₗₑₐₖ) increases exponentially, and the increase in leakage current (Iₗₑₐₖ) causes a rapid increase in static power, as shown in FIG. 1(a). It is expected that static power will be greater than dynamic power below 20 nm line width.

In addition, as shown in FIG. 1(b), the length or the number of stacks of interconnects connecting semiconductor devices rapidly increases as the size of a semiconductor decreases. Thus, the parasitic capacitance (Cₜₒₜ) of an interconnect layer and the interconnect resistance also increase. The interconnect layer occupies 50% or more of the total power consumption of an integrated circuit (IC) due to a rapid increase in interconnect resistance. Since power consumption in interconnects increases in proportion to the parasitic capacitance, there is no improvement method other than a method of using a low-resistance metal or an insulating film having a low dielectric material. Additionally, RC delay due to high capacitance and interconnect resistance generates a signal delay and has an effect on high-speed operation, as shown in FIG. 1(c).

FIG. 2 is a view for explaining the prior research capable of reducing the power consumption of an interconnect layer.

Referring to FIG. 2, as a technology for reducing power consumption of an interconnect layer in the prior art, there have been processes such as dual damascene, super-via, and semi-damascene, and an attempt to reduce the power consumption of the interconnect layer by changing the material of the interconnects.

In recent years, as a technology for reducing power consumption of an interconnect layer, smart interconnect technology has been introduced. Here, the smart interconnect technology is a technology that dramatically reduces power consumption by integrating devices that perform memory or logic functions in the BEOL (Back-End-Of-Line) of CMOS architecture. It serves to perform special functions such as power gating, reconfigurable interconnect, logic-in-memory, etc.

In order to implement a smart interconnect technology, the devices integrated into the interconnects must have an ultra-low leakage current of less than 100 fA, and have compatibility with BEOL processes and materials.

One of the emerging devices is the mechanical interconnect memory, which has a high potential for application in ultra-low-power next-generation semiconductor architectures.

FIGS. 3(a) and 3(b) are diagrams for explaining a conventional mechanical interconnect memory and its operation.

Referring to FIG. 3(a), conventional mechanical interconnect memories distinguish states through direct metal-to-metal contact. These conventional mechanical interconnect memories have a near-zero leakage current (<100 fA), compatibility with BEOL processes and materials (all metal & dielectric), high temperature stability (>200° C.), and high radiation stability (>5 Mrad). In addition, if the adhesion force between the movable beam and operating electrode (electrode A or electrode B) is greater than the restoring force of the movable beam, the movable beam has a non-volatile property that the movable beam continues to adhere to electrode A or electrode B.

For example, referring to FIG. 3(b), if the end of the movable beam of the conventional mechanical interconnect memory is adhered to the electrode A, it may be programmed as “1”, and the end of the movable beam is adhered to the electrode B, it may be erased as “0”.

FIG. 4 is a view for explaining the operating voltage (Vₒₚₑᵣₐₜᵢₒₙ) of the conventional mechanical interconnect memory shown in FIG. 3.

Referring to FIG. 4, the conventional mechanical interconnect memory has the following limitations because the movable beam is bent in the lateral direction by the electrostatic force.

(1) The width (W) and gap (G) of the conventional mechanical interconnect memory are determined by the limit of the lithography tools;

(2) In order to lower the CMOS driving voltage level, the length (l) of the beam must be very long; and

(3) It is difficult to design for non-volatility because the contact area where the end of the beam contacts electrode A or electrode B cannot be accurately known.

FIG. 5 is related to drawings for explaining the thermal property of a nanostructure. FIG. 5(a) is a graph of thermal/electrical conductivity according to the size of a material, and FIG. 5(b) is related to drawings for explaining the thermal conductivity and thermal isolation phenomena of an air-suspended nanostructure.

Referring to FIG. 5(a), thermal/electrical conductivity is decreased due to an increase in electron and phonon scattering in a nano-scale region.

Referring to FIG. 5(b), in the nanostructure suspended in the air, a thermal isolation phenomenon is exhibited by a decrease in the thermal conductivity of a local area at a high temperature. Recently, various studies on the thermal property of graphene and carbon nanotubes in a nano-scale region have been reported.

### SUMMARY OF THE INVENTION

A task of the present invention is to provide a mechanical interconnect memory capable of overcoming the limitations of the conventional mechanical interconnect memory driven in the lateral direction.

In addition, another task of the present invention is to provide a mechanical interconnect memory that can be applied to next-generation ultra-low power semiconductor architectures performing special functions such as power gating, reconfigurable interconnect, and logic-in-memory.

A mechanical interconnect memory according to an embodiment of the present invention comprises: an upper electrode including: a spring part having at least one upward protruding portion between both ends of the spring part; and a moving part having one end of the moving part fixed to the at least one upward protruding portion of the spring part and the other end of the moving part being a free end of the moving part that is capable of moving up and down, and a lower electrode at least partially disposed under the moving part.

Here, the other end of the moving part and the lower electrode may be maintained in an adhered state after the other end of the moving part is in contact with the lower electrode by an electrostatic driving method based on a potential difference between the moving part of the upper electrode and the lower electrode, and a part of the spring part may be thermally expanded upward by current flowing into the spring part of the upper electrode, and thereby the other end of the moving part may be separated from the lower electrode.

Here, a part of the spring part has at least one bent portion or has an upward convex arc shape.

Here, the spring part may generally have an upward convex arc shape or an upwardly pointed triangular shape.

Here, the spring part may include a plurality of spring units arranged side by side in parallel, and the upper electrode may further include a connection part for connecting the plurality of spring units to each other.

Here, the moving part may have a step part in at least one portion of the moving part, and the step part may be a part stepped down by a predetermined length from a part between both ends of the moving part.

Here, the moving part may include a plurality of moving units extending in plurality from a part of the spring part, the length of the plurality of moving units may be different from each other, and the moving part may further include a control electrode disposed under the plurality of moving units and disposed between the spring part and the lower electrode.

Here, the plurality of moving units sequentially may contact the lower electrode as the voltage applied to the control electrode increases.

By using the mechanical interconnect memory according to an embodiment of the present invention, it is possible to overcome the limitations of the conventional lateral driving type mechanical interconnect memory. Specifically, there are advantages in that the performance of the mechanical interconnect memory can be determined according to a deposition thickness regardless of the resolution of lithography equipment, and the length of a moving part (or beam) can be appropriately controlled to lower a driving voltage to a level of CMOS driving voltage, and the contact area between the moving part and a lower electrode can be precisely defined.

In addition, through special functions such as power gating, reconfigurable interconnect, and logic-in-memory, there is an advantage that the mechanical interconnect memory can be applied to next-generation ultra-low power semiconductor architectures.

### BRIEF DESCRIPTION OF THE DRAWINGS

FIGS. 1(a) to 1(c) are graphs for explaining a fundamental problem that occurs according to the miniaturization of a semiconductor.

FIG. 2 is a view for explaining the prior art capable of reducing the power consumption of an interconnect layer.

FIGS. 3(a) and 3(b) are diagrams for explaining a conventional mechanical interconnect memory and its operation.

FIG. 4 is a view for explaining an operating voltage (Vₒₚₑᵣₐₜᵢₒₙ) of the conventional mechanical interconnect memory shown in FIG. 3.

FIG. 5 relates to drawings for explaining the thermal property of a nanostructure. FIG. 5(a) is a graph of thermal/electrical conductivity according to the size of a material, and FIG. 5(b) relates to drawings for explaining the thermal conductivity and isolation phenomenon of an air-suspended nanostructure.

FIG. 6 is a perspective view of a mechanical interconnect memory viewed from one side according to an embodiment of the present invention.

FIGS. 7(a) to 7(e) are cross-sectional views for explaining modified examples of the spring part 153 in FIG. 6.

FIGS. 8 to 9 are views for explaining an operation mechanism of the mechanical interconnect memory according to the embodiment of the present invention shown in FIG. 6.

FIG. 10(a) is a perspective view of a modified example of the mechanical interconnect memory shown in FIG. 6 as viewed from one side, and FIG. 10(b) is a simulation graph comparing the performances of the mechanical interconnect memory shown in FIG. 10(a) and the mechanical interconnect memory shown in FIG. 6.

FIG. 11 is a perspective view of a mechanical interconnect memory viewed from one side according to another embodiment of the present invention.

FIG. 12 is a perspective view of a mechanical interconnect memory viewed from one side according to another embodiment of the present invention.

FIG. 13 is a graph for explaining the implementation of the mechanical interconnect memory as a multi-bit interconnect memory according to another embodiment of the present invention shown in FIG. 12.

FIG. 14 is a view for explaining a case in which the mechanical interconnect memory according to various embodiments of the present invention is applied to a semiconductor architecture and extended to a system level.

FIG. 15 is a diagram schematically illustrating an example and a manufacturing method of applying the mechanical interconnect memory according to various embodiments of the present invention to a system level.

FIG. 16 is a diagram in which the mechanical interconnect memory shown in FIG. 6 is applied to an actual CMOS BEOL (Back-End-Of-Line).

### DETAILED DESCRIPTION

Hereinafter, a detailed description of preferred embodiments of the present invention is described with reference to accompanying drawings. It should be noted that reference numerals and identical elements in the drawings are indicated by the same reference numerals as much as possible even if they are indicated on different drawings. For reference, in describing the present invention, if it is determined that a detailed description of a related known function or configuration may unnecessarily obscure the gist of the present invention, the detailed description thereof will be omitted.

FIG. 6 is a perspective view of a mechanical interconnect memory viewed from one side according to an embodiment of the present invention.

Referring to FIG. 6, a mechanical interconnect memory according to an embodiment of the present invention includes a lower electrode 110 and an upper electrode 150, and it may further include terminals 170, 175 connected respectively to both ends of the upper electrode 150 and/or support parts 190, 195 disposed below the terminals 170, 175.

The upper electrode 150 includes a moving part 151 and a spring part 153.

The moving part 151 has a shape extending from a portion of the spring part 153 in a direction different from the longitudinal direction of the spring part 153 by a predetermined length. Here, the different direction may be a direction perpendicular to the longitudinal direction of the spring part 153.

One end of both ends of the moving part 151 is a fixed end connected to the spring part 153, and the other end is a free end that can move up and down. The moving part 151 has a cantilever or cantilever structure. Here, one end of the moving part 151 is connected to a part protruding upward from the spring part 153.

The moving part 151 is movable up and down. The moving part 151 is movable up and down by an electrostatic driving method based on a potential difference with the lower electrode 161.

The lower electrode 110 is disposed under the other end of the moving part 151. The other end of the moving part 151 may be adhered to the lower electrode 110 by the electrostatic driving method.

The spring part 153 is connected between the two terminals 170, 175. The spring part 153 may be connected between the two terminals 170, 175 to be suspended in the air.

At least a portion or the entirety of the spring part 153 between both ends protrudes upward. For example, as shown in FIG. 6, the at least one portion of the spring part 153 may have two bent parts and may have a rectangular shape. Here, the shape of the at least one portion of the spring part 153 is not limited thereto. For example, the at least one portion of the spring part 153 may be bent in a direction of expansion or may have a curved upward structure. It will be described in more detail with reference to FIG. 7.

FIGS. 7(a) to 7(e) are cross-sectional views for explaining modified examples of the spring part 153 in FIG. 6.

Referring to FIG. 7(a), at least a portion between both ends of the spring part 153 may have two bent parts bent upward, and may have a rhombus shape.

Referring to FIG. 7(b), at least a portion between both ends of the spring part 153 may have one bent part bent upward, and may have a triangular shape.

Referring to FIG. 7(c), at least a portion between both ends of the spring part 153 may be convex upward and may have an arcuate shape.

Referring to FIG. 7(d), the spring part 153 may have one bent part pointed upward in the center, and may have a triangular shape as a whole.

Referring to FIG. 7(e), the spring part 153 may have an arc shape with an upward convex shape.

Referring to FIG. 6 again, the lower electrode 110 is disposed under the moving part 151 of the upper electrode 150. More specifically, one end of the lower electrode 110 is disposed below the other end of the moving part 151 at a predetermined distance apart.

The terminals 170, 175 are respectively connected to both ends of the upper electrode 150. The terminals 170, 175 may include a first terminal 170 connected to one end of both ends of the upper electrode 150 and a second terminal 175 connected to the other end of the upper electrode 150. The upper electrode 150 may be suspended from a bottom surface by the terminals 170, 175.

The support parts 190, 195 are disposed below the terminals 170, 175 to support the terminals 170, 175. The support parts 190, 195 may include a first support part 190 disposed under the first terminal 170 and a second support part 195 disposed under the second terminal 175. The upper electrode 150 may be suspended from a bottom by the height of the support parts 190, 195.

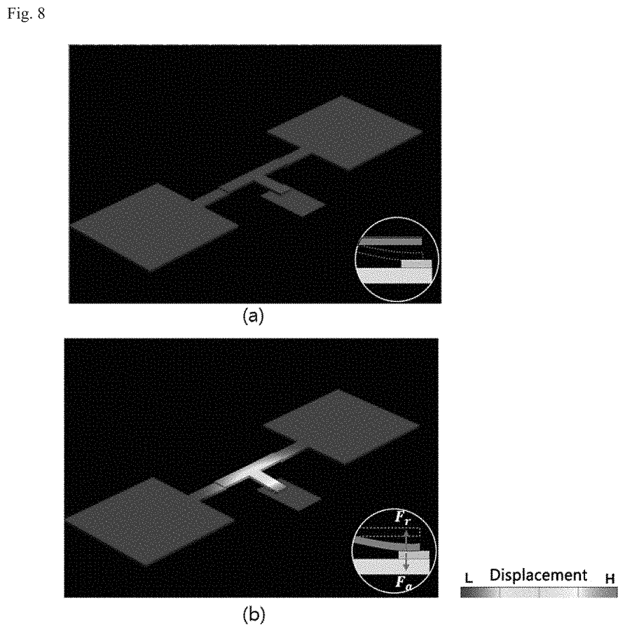

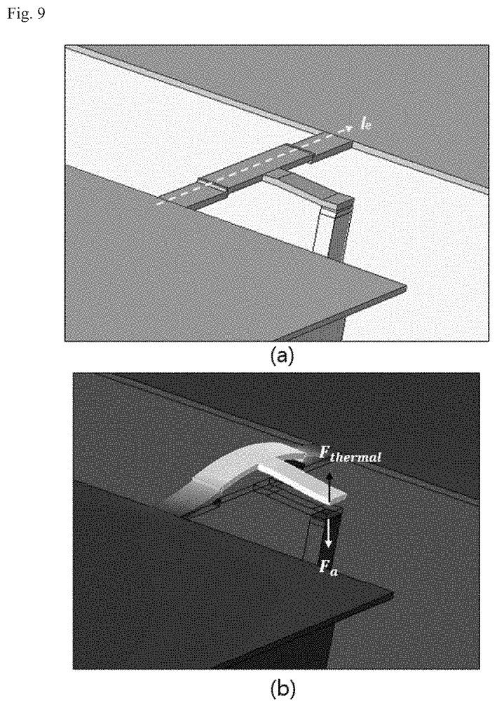

As described above, in the mechanical interconnect memory according to an embodiment of the present invention shown in FIG. 6, the moving part 151 of the upper electrode 150 is in contact with the lower electrode 110 by an electrostatic driving method based on a potential difference between the lower electrode 110 and the upper electrode and 150. Here, if the potential difference between the lower electrode 110 and the upper electrode 150 is equal to or greater than an operating voltage, the moving part 151 of the upper electrode 150 may move in a direction toward the lower electrode 110 and may be in contact with the lower electrode 110. In addition, if the adhesion force between the moving part 151 of the upper electrode 150 and the lower electrode 110 is greater than the restoring force of the moving part 151 of the upper electrode 150, the moving part 151 of the upper electrode 150 may remain adhered to the lower electrode 110. Meanwhile, an electrothermal driving method is used to overcome the adhesion force between the moving part 151 and the lower electrode 110. The electrothermal driving method is driven by thermal expansion in an upper direction of the spring part 153 of the upper electrode 150. It will be described in detail with reference to FIGS. 8 to 9.

FIGS. 8 to 9 are diagrams for explaining an operation mechanism of the mechanical interconnect memory according to an embodiment of the present invention shown in FIG. 6.

FIG. 8 is a view for explaining a program operation mechanism of a mechanical interconnect memory according to an embodiment of the present invention shown in FIG. 6. FIG. 8(a) is a FEM displacement simulation diagram before the program operation, and FIG. 8(b) is a FEM displacement simulation diagram after the program operation.

As shown in FIG. 8(a), in a state in which the moving part 151 of the upper electrode 150 and the lower electrode 110 are separated from each other with an air gap therebetween, if more than an operating voltage (pull-in voltage) is applied between the upper electrode 150 and the lower electrode 110, a pull-in phenomenon occurs while the other end of the moving part 151 of the upper electrode 150 is in contact with the lower electrode 110, as shown in FIG. 8(b).

If the adhesion force (F_{c}) between the moving part 151 and the lower electrode 110 of the upper electrode 150 is greater than the restoring force (Fr) of the moving part 151, the moving part 151 of the upper electrode 150 and the lower electrode 110 may maintain an adhered state even if the voltage applied between the upper electrode 150 and the lower electrode 110 is removed. As described above, the phenomenon of maintaining the adhesion state may be referred to as an electrostatic driving program, and a program operation of a nonvolatile memory device may be achieved.

FIG. 9 is a view for explaining an erase operation mechanism of the mechanical interconnect memory according to an embodiment of the present invention shown in FIG. 6. FIG. 9(a) is a simulation of FEM displacement before the erase operation, and FIG. 9(b) is a simulation of FEM displacement after the erase operation.

As shown in (a) of FIG. 9, in a state in which the moving part 151 of the upper electrode 150 and the lower electrode 110 are adhered to each other, if a predetermined current (Iₑ) flows through the spring part 153 of the upper electrode 150, a thermal expansion in an upward direction (or +Z-direction) occurs due to Joule heat, as shown in FIG. 9(b).

If the force (Fₜₕₑᵣₘₐₗ) of the thermal expansion is greater than the adhesion force (F_{adhesion}) between the moving part 151 of the upper electrode 150 and the lower electrode 110, the adhesion state is overcome. As described above, the phenomenon in which the adhesion state is overcome may be referred to as an electrothermal driving erase.

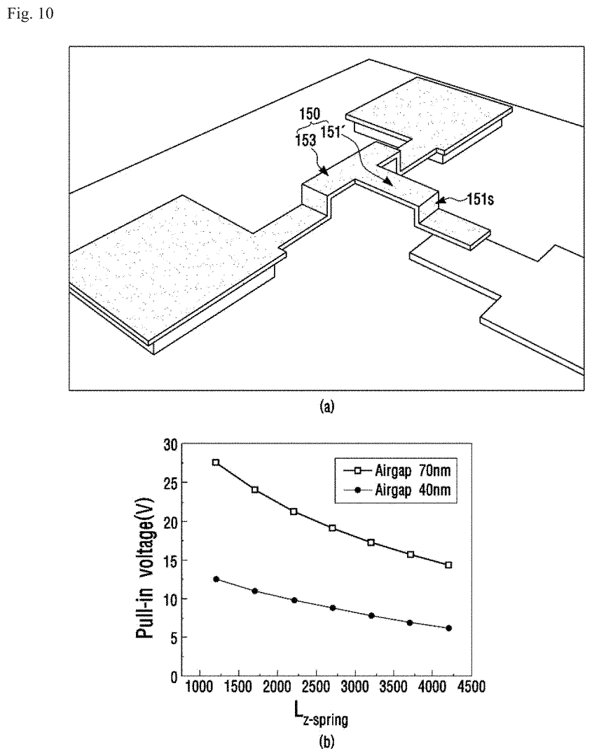

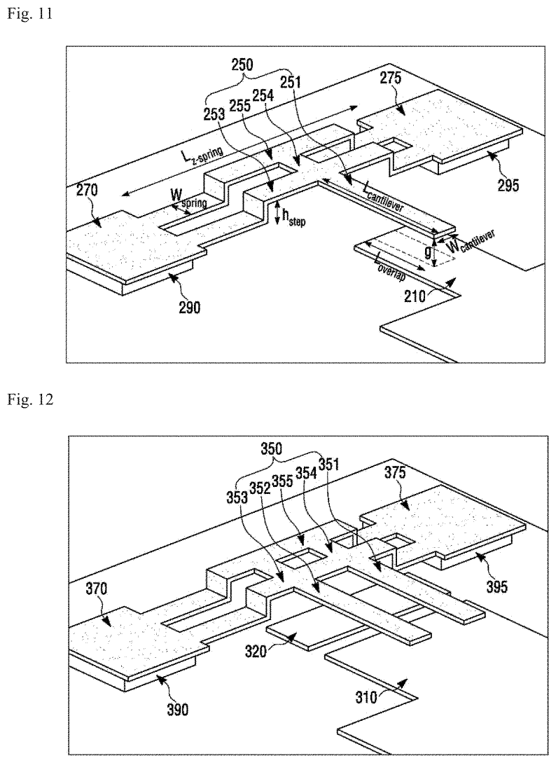

FIG. 10(a) is a perspective view of a modified example of the mechanical interconnect memory shown in FIG. 6 as viewed from one side, and FIG. 10(b) is a simulation graph comparing the performances of the mechanical interconnect memory shown in FIG. 10(a) and the mechanical interconnect memory shown in FIG. 6.

The mechanical interconnect memory according to the modified example shown in FIG. 10(a) is different from the mechanical interconnect memory shown in FIG. 6 in the moving part 151′, and the rest is the same.

The moving part 151′ has a step part 151s in at least one portion.

The step part 151s is a part stepped down by a predetermined length from a portion between both ends of the moving part 151′.

The step portion 151s may form a predetermined angle with the other end of the moving portion 151′. Here, the predetermined angle may be a right angle or an obtuse angle.

The other end of the moving part 151′ may be disposed closer to the lower electrode 110 by the step part 151s. That is, the air gap between the other end of the moving part 151′ and the lower electrode 110 is narrower than that of the mechanical interconnect memory of FIG. 6.

Accordingly, since the air gap between the moving part 151′ and the lower electrode 110 is smaller, there is an advantage in that it can be driven at a lower operating voltage and faster speed during programming than the mechanical interconnect memory of FIG. 6.

The graph of FIG. 10(b) shows a simulation result in comparison with the pull-in voltage (V) of the mechanical interconnect memory of FIG. 10(a) and the pull-in voltage (V) of the mechanical interconnect memory of FIG. 6, according to the length (L_{z-spring}) of the spring part 153.

In FIG. 10(b), “Airgap 70 nm” means an air gap between the other end of the moving part 151 and the lower electrode 110 in FIG. 6, and “Airgap 40 nm” means an air gap between the other end of the moving part 151′ of the mechanical interconnect memory and the lower electrode 110 in FIG. 10(a).

Referring to FIG. 10(b), if the mechanical interconnect memory of FIG. 10(a) and the mechanical interconnect memory of FIG. 6 have the same length of the spring part 153, it can be seen that a lower operating voltage in the case of the mechanical interconnect memory of FIG. 10(a) can be obtained than in the case of the mechanical interconnect memory of FIG. 6.

FIG. 11 is a perspective view of a mechanical interconnect memory viewed from one side according to another embodiment of the present invention.

Referring to FIG. 11, the mechanical interconnect memory according to another embodiment of the present invention includes a lower electrode 210 and an upper electrode 250. The mechanical interconnect memory according to another embodiment of the present invention may further include terminals 270, 275 and/or support parts 290, 295.

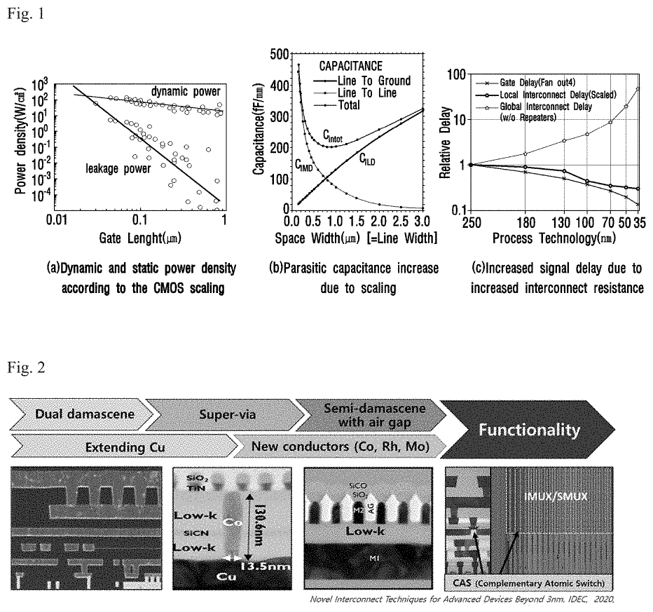

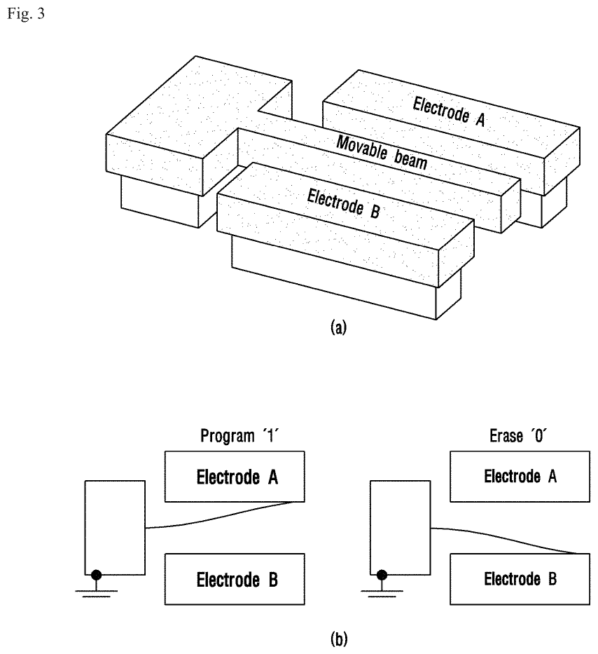

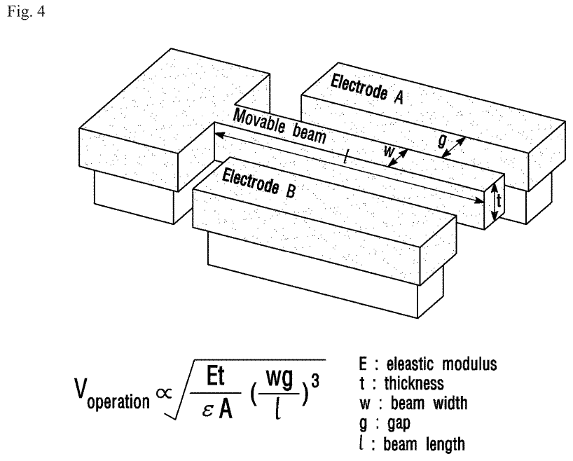

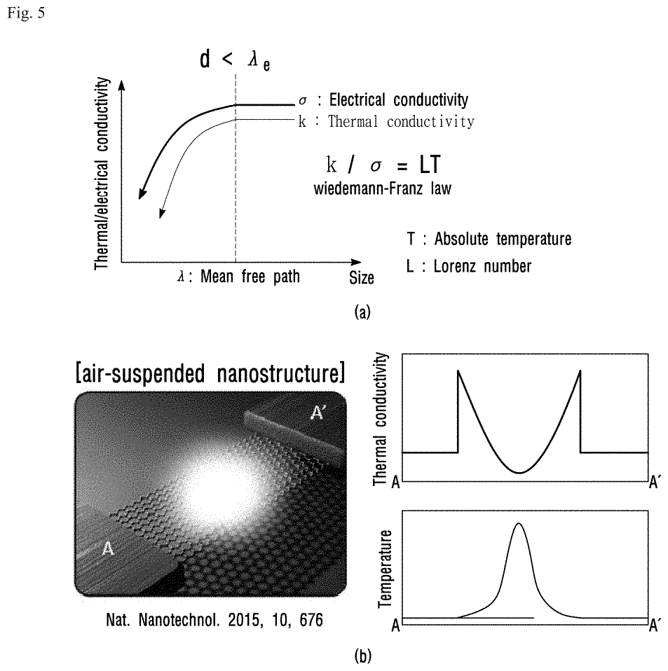

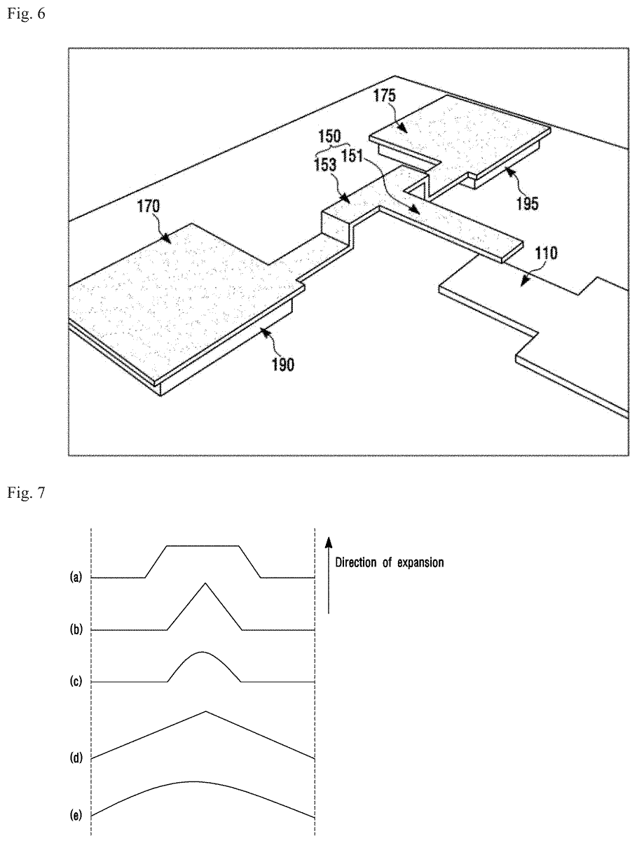

The lower electrode 210, the terminals 270, 275, and the supporting parts 290, 295 shown in FIG. 1I are the same as the lower electrode 110, the terminals 170, 175, and the supporting parts 190, 195 shown in FIG. 6. Thus, descriptions thereof are replaced with those described above, and the upper electrode 250 will be described in detail below.

The upper electrode 250 may include a moving part 251, a plurality of spring units 253, 255, and a connection part 254.

Both ends of each of the spring units 253, 255 are respectively connected to the two terminals 270, 275, and at least a portion between the both ends protrudes upward. Here, the shape of each of the spring units 253, 255 may be one of those shown in FIGS. 7(a) to 7(e). In addition, a portion of a first spring unit 253 and a portion of a second spring unit 255 may have the same shape or different shapes.

The plurality of spring units 253, 255 may be arranged side by side in parallel. Although the drawing shows two spring units, they are not limited thereto, and the number of spring units may be three or more.

The connection part 254 connects between the plurality of spring units 253, 255. Here, the connecting part 254 may be located in a longitudinal direction of the moving part 251. The connection part 254 may connect between portions of the plurality of spring units 253, 255. The connection part 254 may be one or multiple.

The moving part 251 may extend in a direction different from a longitudinal direction of the spring part 253 in a portion between both ends of any one of plurality of spring units 253, 255. One end of the moving part 251 is a fixed end to the spring unit 253, and the other end is a free end movable up and down.

The mechanical interconnect memory shown in FIG. 1I has a plurality of spring units 253, 255, compared with the mechanical interconnect memory shown in FIG. 6. There is an advantage of being able to implement a higher thermal expansion force at a lower temperature through the plurality of spring units 253, 255 in comparison with the case of the mechanical interconnect memory of FIG. 6.

In addition, in designing the mechanical interconnect memory shown in FIG. 11, the design elements include the length (L_{z-spring}) and width (W_{spring}) of the spring parts 253, 255, the height (hₛₜₑₚ) of a portion of the spring parts 253, 255, the length (L_{cantilever}) and width (W_{cantilever}) of the moving part 251, the air gap (g) between the moving part 251 and the lower electrode 210, the overlapping area (Lₒᵥₑᵣₗₐₚ*W_{cantilever}) between the moving part 251 and the lower electrode 210, etc. The operating voltage, contact resistance, operating speed, operating power, etc. of the mechanical interconnect memory can be precisely controlled by adjusting the design elements. The same is true for the mechanical interconnect memory shown in FIG. 6.

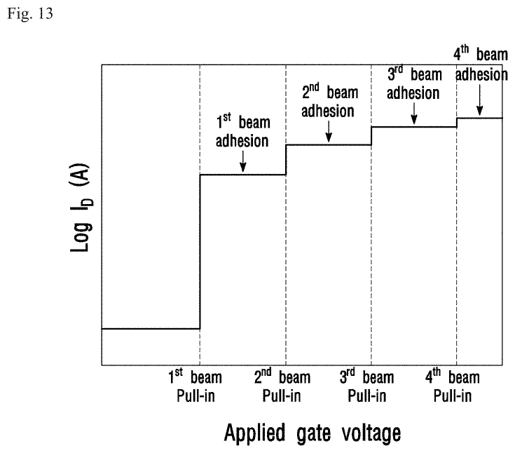

FIG. 12 is a perspective view of a mechanical interconnect memory, viewed from one side, according to another embodiment of the present invention, and FIG. 13 is a graph to explain the implementation of the mechanical interconnect memory according to another embodiment of the present invention shown in FIG. 12 to a multi-bit mechanical interconnect memory.

The mechanical interconnect memory shown in FIG. 12 is different from the mechanical interconnect memory shown in FIG. 11 in the upper electrode 350. In particular, there is a difference in that it has a plurality of connecting parts 354 and a plurality of moving parts 351, 352. Since the remaining lower electrode 310, the terminals 370, 375, and the supporting parts 390, 395 are the same, their description is replaced with the above description.

The plurality of moving parts 351, 352 of mechanical interconnect memory shown in FIG. 12 has different lengths.

In addition, the mechanical interconnect memory shown in FIG. 12 may further include a control electrode 320.

The control electrode 320 is disposed below the plurality of moving parts 351, 352, and is disposed between the spring part 353 and the lower electrode 310.

As a driving voltage applied to the control electrode 320 increases, the plurality of moving parts 351, 352 are sequentially adhered to the lower electrode 310, and a current therebetween changes depending on the number of the moving parts 351, 352 adhered to the lower electrode 310. Thus, a multi-bit interconnect memory can be implemented.

For example, FIG. 13 is a graph for explaining that a multi-bit is implemented in the case that the plurality of moving parts 351, 352 of mechanical interconnect memory shown in FIG. 12 is extended to four.

If the first terminal 270 functions as a source, the lower electrode 310 functions as a drain, and the control electrode 320 functions as a gate as shown in FIG. 12, it can be seen that as the voltage applied to the gate increases, the four moving parts having different lengths are sequentially adhered to the lower electrode 310 and the current (ID) flowing through the drain is changed, as shown in FIG. 13.

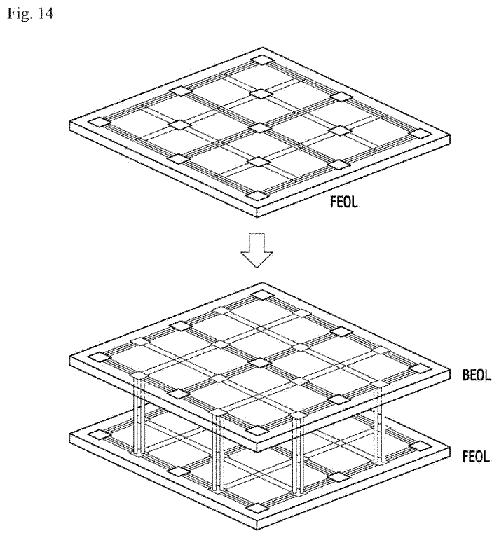

FIG. 14 is a view for explaining a case in which the mechanical interconnect memory according to various embodiments of the present invention is applied to a semiconductor architecture and extended to a system level.

Referring to the upper drawing of FIG. 14, in the conventional semiconductor architecture, both calculation and storage are performed in a Front-End-Of-Line (FEOL).

However, as shown in the lower drawing of FIG. 14, in the semiconductor architecture to which the mechanical interconnect memory according to various embodiments of the present invention is applied, the storage of the calculation result may be performed in the Back-End-Of-Line (BEOL), which is the interconnect layer. Accordingly, compared to the conventional semiconductor architecture, there are advantages such as reduction in overall footprints, increase in operation speed due to reduction in interconnects, and reduction in power consumption.

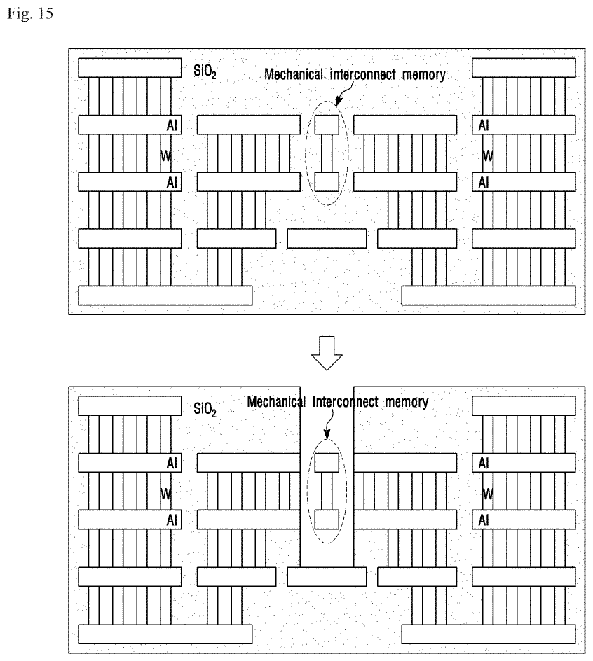

FIG. 15 is a diagram schematically illustrating an example and a manufacturing method of applying the mechanical interconnect memory according to various embodiments of the present invention to a system level.

Since the mechanical interconnect memory according to various embodiments of the present invention is made of only metal, it is compatible with the existing CMOS BEOL (Back-End-Of-Line) process and material, and thus can be implemented through interconnects.

Referring to the upper drawing of FIG. 15, a space for the moving part of the mechanical interconnect memory to mechanically move is required. Therefore, to form a space in which the moving part of the mechanical interconnect memory can mechanically move, as shown in the lower drawing of FIG. 15, a release process that partially etches a portion of an insulating layer (SiO₂) surrounding the mechanical interconnect memory may be utilized for implementation thereof.

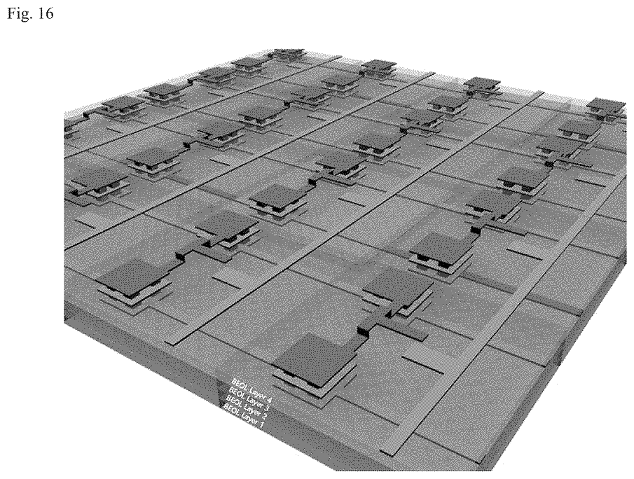

FIG. 16 is a diagram in which the mechanical interconnect memory shown in FIG. 6 is applied to an actual CMOS Back-End-Of-Line (BEOL).

Referring to FIG. 16, in an actual CMOS BEOL, a plurality of mechanical interconnect memories shown in FIG. 6 may be arranged in a matrix on one or more BEOL layers (BEOL Layers 1, 2, 3, 4). Since the insulating layer is removed around each mechanical interconnect memory, the moving part of each mechanical interconnect memory can move up and down to perform a memory function.

The mechanical interconnect memories according to various embodiments of the present invention described above with reference to FIGS. 6 to 16 are the world's first non-volatile nano electrothermal driving mechanical interconnect memories, and their driving methods in configuration and operation are completely different from the conventional lateral driving method in which a moving beam is laterally driven. In addition, as a structure of the spring part optimized for vertical driving is applied, there is an advantage that an efficient erase operation is possible by the action of thermal expansion force in the opposite direction to that of an adhesion force. Further, there is an advantage of being able to implement the world's first nano electrothermal driving memory-based logic-in-memory. In particular, the mechanical interconnect memory shown in FIG. 12 has the advantage of being able to implement the world's first multi-bit by additionally using a plurality of moving parts and control electrodes.

Furthermore, mechanical interconnect memories according to various embodiments of the present invention have very small footprint characteristics because they do not need to have a long beam length due to being vertically driven, have low contact resistance (high reliability) because they can be defined with a clear contact area, and enable their ultra-low-power, ultra-fast operations using heat concentration effects at a nanoscale, in comparison with laterally driven interconnect memories. In addition, since the mechanical interconnect memories are made of only metal, they are 100% compatible with the existing CMOS BEOL processes and materials, and there is a very high possibility that they can be applied to a system level in comparison with other new memories (RRAM, MRAM, PRAM, etc.).

Some embodiments of the present invention have been described above with reference to accompanying drawings, but these are merely examples and do not limit the present invention. It will be appreciated that various modifications and applications thereof not exemplified above can be made by those skilled in the art to which the present invention pertains to the extent without departing from the essential characteristics of the embodiments. For example, each configuration specifically shown in an embodiment can be implemented by modifications and applications thereof. The differences related to such modifications and applications should be construed as being included in the scope of the present invention defined in the appended claims.

What is claimed is:

1. A mechanical interconnect memory comprising:
an upper electrode including: a spring part having at least one upward protruding portion between both ends of the spring part; and a moving part having one end of the moving part fixed to the at least one upward protruding portion of the spring part and the other end of the moving part being a free end of the moving part that is capable of moving up and down; and
a lower electrode at least partially disposed under the moving part.

2. The mechanical interconnect memory of claim 1, wherein the other end of the moving part and the lower electrode are maintained in an adhered state after the other end of the moving part is in contact with the lower electrode by an electrostatic driving method based on a potential difference between the moving part of the upper electrode and the lower electrode, and
a part of the spring part is thermally expanded upward by a current flowing into the spring part of the upper electrode, and thereby the other end of the moving part is separated from the lower electrode.

3. The mechanical interconnect memory of claim 1, wherein a part of the spring part has at least one bent portion or has an upward convex arc shape.

4. The mechanical interconnect memory of claim 1, wherein the spring part generally has an upward convex arc shape or an upwardly pointed triangular shape.

5. The mechanical interconnect memory of claim 1, wherein the spring part includes a plurality of spring units arranged side by side in parallel, and
the upper electrode further includes a connection part for connecting the plurality of spring units to each other.

6. The mechanical interconnect memory of claim 1, wherein the moving part has a step part in at least one portion of the moving part, and the step part is a part stepped down by a predetermined length from a part between both ends of the moving part.

7. The mechanical interconnect memory of claim 1, wherein the moving part includes a plurality of moving units extending in plurality from a part of the spring part, the length of the plurality of moving units is different from each other, and the moving part further includes a control electrode disposed under the plurality of moving units and disposed between the spring part and the lower electrode.

8. The mechanical interconnect memory of claim 7, wherein the plurality of moving units sequentially contacts the lower electrode as a voltage applied to the control electrode increases.

9. A computing system comprising:
a mechanical interconnect memory arranged in plurality on one or more of BEOL (Back-End-Of-Line) layers; and
an insulating layer disposed on the remaining region except around the mechanical interconnect memory,
wherein the mechanical interconnect memory comprises:
an upper electrode including: a spring part having at least one upward protruding portion between both ends of the spring part; and a moving part having one end of the moving part fixed to the at least one upward protruding portion of the spring part and the other end of the moving part being a free end of the moving part that is capable of moving up and down; and
a lower electrode at least partially disposed under the moving part.

10. The computing system of claim 9, w % herein the other end of the moving part and the lower electrode are maintained in an adhered state after the other end of the moving part is in contact with the lower electrode by an electrostatic driving method based on a potential difference between the moving part of the upper electrode and the lower electrode, and
a part of the spring part is thermally expanded upward by a current flowing into the spring part of the upper electrode, and thereby the other end of the moving part is separated from the lower electrode.

11. The computing system of claim 9, wherein a part of the spring part has at least one bent portion or has an upward convex arc shape.

12. The computing system of claim 9, wherein the spring part generally has an upward convex arc shape or an upwardly pointed triangular shape.

13. The computing system of claim 9, wherein the spring part includes a plurality of spring units arranged side by side in parallel, and
the upper electrode further includes a connection part for connecting the plurality of spring units to each other.

14. The computing system of claim 9, wherein the moving part has a step part in at least one portion of the moving part, and the step part is a part stepped down by a predetermined length from a part between both ends of the moving part.

15. The computing system of claim 9, wherein the moving part includes a plurality of moving units extending in plurality from a part of the spring part, the length of the plurality of moving units is different from each other, and the moving part further includes a control electrode disposed under the plurality of moving units and disposed between the spring part and the lower electrode.

16. The computing system of claim 15, wherein the plurality of moving units sequentially contacts the lower electrode as a voltage applied to the control electrode increases.
